(19) United States
(12) Patent Application Publication
(10) Pub. No.: US 2010/0321126 A1
(43) Pub. Date: Dec. 23, 2010

(54) Method of Modulating A Carrier to Transmit Power to a Device, and Modulator Adapted to do the Same

(76) Inventor: Robert John Castle, Bristol (GB)

Correspondence Address: HEWLETT-PACKARD COMPANY;Intellectual Property Administration, 3404 E. Harmony Road, Mail Stop 35, FORT COLLINS, CO, 80528, US

(21) Appl. No.: 12/865,595

(22) PCT Filed: Apr. 22, 2008
(86) PCT No.: PCT/EP2008/054848

§ 371 Date: Jul. 30, 2010

(51) Int. Cl. H03C 3/38; H03D 1/00

(52) U.S. Cl. 332/145; 329/350

(57) ABSTRACT

A receiver for recovering timing and data information from a signal, comprising an envelope detector for demodulating the signal; to produce a demodulated signal; a filter for filtering the demodulated signal to remove or attenuate amplitude variations due to the timing information so as to produce a data signal; and a timing recovery circuit for forming a difference between time aligned versions of the demodulated signal and the data signal so as to recover the timing information.

### FIELD OF THE INVENTION

The present invention relates to a method of and apparatus for modulating a carrier to provide both power and data trans mission to a device irradiated by the carrier.

### SUMMARY OF THE INVENTION

According to a first aspect of the present invention there is provided a modulation scheme for modulating a signal transmitted from a first device to a second device which is energised by the signal, wherein the first device is further arranged to amplitude modulate the signal at a data rate, and wherein the method further comprises phase modulating the signal at a clock rate synchronised with the data rate, and wherein the phase modulation is arranged to cause a non-monotonic change in the signal amplitude.

It is thus possible to provide a transmission scheme which adds a phase modulation to an amplitude modulation signal such that the phase modulation spreads the transmitted signal in the frequency domain and reduces the peak in the power spectral density of the transmitted signal compared to an equivalent signal in which no phase modulation has been applied.

According to a second aspect of the present invention there is provided a reader/writer device for use with a passive device arranged to be irradiated with RF energy by the reader/writer device, wherein the reader/writer device modulates an RF carrier in accordance with the first aspect of the present invention.

According to a third aspect of the present invention there is provided a receiver for recovering timing and data information from a signal, comprising an envelope detector for demodulating the signal to produce a demodulated signal; a filter for filtering the demodulated signal to remove or attenuate amplitude variations due to the timing information so as to produce a data signal; and a timing recovery circuit for forming a difference between time aligned versions of the demodulated signal and the data signal so as to recover the timing information.

According to a fourth aspect of the present invention there is provided a passive device including a receiver according to the third aspect of the present invention.

### BRIEF DESCRIPTION OF THE DRAWINGS

The present invention will further be described, by way of non-limiting example only, with reference to the accompanying Figures, in which:

FIG. 1 schematically illustrates a memory spot device in communication with a reader/writer device.

FIG. 2 schematically illustrates the power spectral density of an amplitude modulated signal used to transmit a Manchester encoded data stream and power from a terminal to a device such as an RF ID tag, memory spot or near field communications device which derives its power from the transmitted signal;

FIG. 3 schematically illustrates a low index modulation, amplitude modulation scheme for use in transmitting data to such a passive device which derives its power from the signal irradiating it;

FIG. 4 schematically illustrates a modulation scheme on a phasor diagram and transitions within the modulation scheme;

FIG. 5 schematically shows a modulator as described in the prior art;

FIG. 6 schematically illustrates an apparatus for generating the phase control signal;

FIG. 7 schematically illustrates an example of a phase modulation signal supplied to a modulator adapted to work in accordance with the present invention;

FIG. 8 illustrates the modulation vector amplitude as a function of position in the transition from constellation point 100 to point 102 in FIG. 7;

FIG. 9 is a plot comparing the amplitude profiles of the different transitions;

FIG. 10 is a plot of phase angle versus time for a plurality of phase transitions;

FIG. 11a is a constellation diagram showing transitions when no data modulation is applied;

FIG. 11b is a constellation diagram showing transitions when data modulation is applied;

FIG. 12 is a graph of transmit data as a function of time;

FIG. 13 is a graph of phase angle versus time;

FIG. 14 is a graph of the power envelope of a signal transmitted in accordance with the present invention;

FIG. 15 is a circuit diagram of a receiver constituting an embodiment of the present invention;

FIG. 16 is a graph of the signal occurring at the output of the moving average filter in the receiver shown in FIG. 15; and

FIG. 17 is a graph of the recovered timing signal.

### DESCRIPTION OF PREFERRED EMBODIMENTS OF THE PRESENT INVENTION

Devices such as RF ID tags or memory spots are known or proposed whereby some memory, optionally some data processing facility and a transmitter/receiver are integrated into a single device, usually a silicon chip. The device does not include an onboard power supply and instead is adapted to be irradiated, for example by radio frequency energy, and to extract sufficient energy from the irradiating signal to power the device up such that it can perform its task. A problem for such devices is that they must receive sufficient energy from the reader/writer device irradiating them that they can function whilst simultaneously there is a desire for these devices to be as inexpensive as possible such that they may be extensively deployed without incurring significant cost.

The radio frequency spectrum is becoming an increasingly congested resource. Therefore the possibility of mutual interference from different systems co-existing within the same physical region can become a real and significant problem. One of the measures used to evaluate an RF transmission is power spectral density, PSD, which refers to the bandwidth over which the signal power from a transmitter is distributed. In general, a transmission with a high power spectral density is more likely to cause interference to other users and devices than a transmission with a low power spectral density. Systems of the type described hereinbefore that use radio frequency transmissions to provide power to passive devices, such as RF ID and memory spot devices, are prone to having a high peak power spectral density because when they are transferring power (without data) to receive a response from the device that they are irradiating, then the transmission is effectively just a single tone. Thus all of the power is concentrated into a very narrow bandwidth and the peak power spectral density can become relatively high. Furthermore, it is also the case that when transferring data from the irradiating device to the passive device the peak power spectral density may still be high because the desire to implement low cost receivers within the passive devices means that AM receivers are used. Furthermore, the requirement to transmit power at all times means that low index amplitude modulation schemes are used.

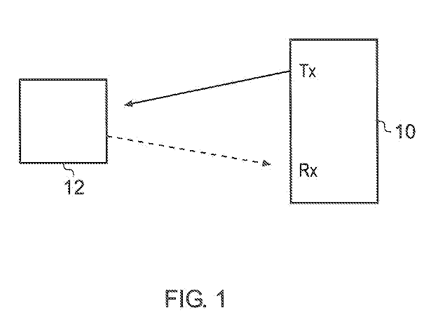

A reader/writer terminal 10 in conjunction with a memory spot device 12 is schematically shown in FIG. 1. The reader/writer includes a transmitter so as to irradiate the memory spot device 12. The reader/writer 10 also includes a receiver for receiving any transmissions from the memory spot device 12.

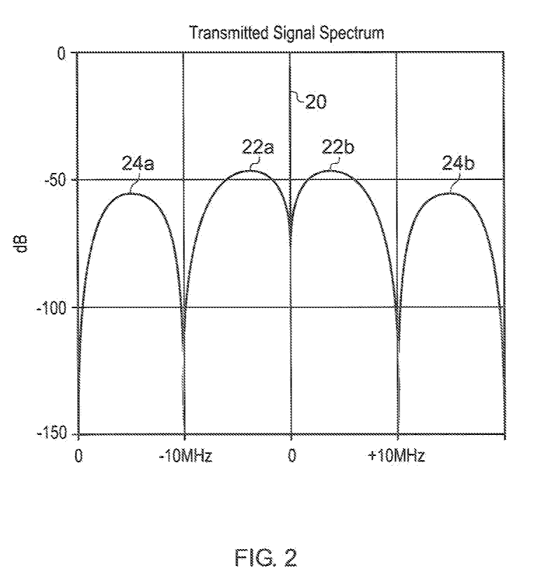

As noted herein before, the current modulator/demodulator used in reader/writer units for memory spot, RF ID tags and other passive computing devices (being passive in the sense that they have no onboard power and must receive their power from the signal irradiating them) can result in a transmitted signal having a high peak power spectral density that has the potential to cause interference with other users. The reader/writer units, out of economic convenience, are often arranged to work in frequency bands which have been designated for general use. Therefore, for example, the reader/writer unit for memory spot operates in the 2.4 GHz band. This band is also shared by other users, such as WiFi networks. The transmission scheme is amplitude modulation with a low modulation index, with the result that the transmission has many of the characteristics of an unmodulated RF carrier. FIG. 2 schematically illustrates a plot of the power spectral density of the signal transmitted by the reader/writer unit 10 of FIG. 1 when transmitting a Manchester encoded data stream. It can be seen that the majority of the power is located in a central peak 20. Side lobes 22a, 22b, 24a and 24b extend in symmetrical manner around the central peak 20. Assuming, for example, that the data transmission rate is 10 MBs⁻¹ (megabits a second) then it can be seen that the peaks in the side lobes 22 a and 22b occur approximately 3.8 MHz away from the central peak 20 and that nulls occur 10 MHz away from the central peak.

It can be seen that the maximum amplitude of the side lobes 22a and 22b are approximately 40 dB lower than the height of the central peak 20. This means that the overwhelming majority of the signal power is concentrated in the spectral tone due to the carrier. The bandwidth of the carrier is very narrow, so when transmitting a signal of the power required to make the memory spot chip function, the peak power spectral density is very high.

The memory spot is produced in a cost conscious regime As a result its components are not trimmed for accuracy. It is therefore advantageous to provide a timing signal such that data is correctly written into memory without, for example, a bit being written twice due to a clock error. The Manchester coding is a self clocking data stream as a signal transition always occurs in the middle of each transmitted bit. From one viewpoint each bit of data supplied to a Manchester encoder gets converted into a pair of bits. As a consequence each transmitted data bit takes twice as long to transmit compared to the un-encoded data stream.

It would be possible to reduce the peak power spectral density by reducing the transmitted power. However this has the problem that the power available to the passive device becomes reduced and it is therefore likely that it would cease to function. Alternatively, more complex modulation schemes could be used which have better power spectral density characteristics. However these are economically unsatisfactory as the existing amplitude modulation scheme used by RF ID tag and memory spot devices is a very good solution to the dual requirements of transferring both power and data to a chip in the manner which uses the minimum amount of silicon area on the chip (which relates directly to the cost thereof) and which also avoids complex and power hungry receiver circuitry. Therefore any change in the modulation scheme away from simple amplitude modulation is likely to have a direct and negative impact on both the price and performance of the system as a whole.

The present inventor s has already realised that it is possible to modify the modulation scheme used in readers/writers for such passive systems so as to reduce the power spectral density transmitted thereby without impacting on the performance of the simple amplitude modulation receiver used within the passive device itself. The teachings are disclosed in GB 2437350 but are summarised here.

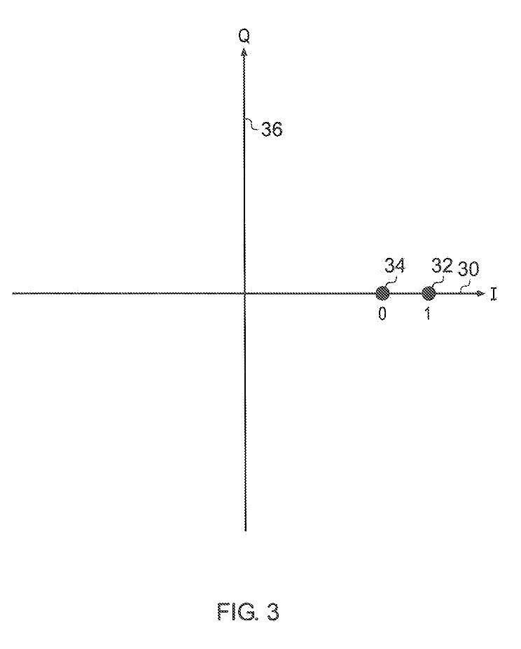

FIG. 3 schematically shows a phasor diagram representing the prior art modulation scheme used for memory spot devices and t he like. Given that no phase modulation occurs in a conventional amplitude modulation scheme, then for simplicity the modulation can be represented as lying along the real (in-phase) axis 30 of the phasor diagram. Furthermore, as a low modulation index is used, then the variation in the transmitted power is relatively small. In this example, a “1” is transmitted with a first power, as indicated 32 on FIG. 3, and the “0” is located with a second power level, in this case a reduced power level, designated 34 in FIG. 3. If the index of modulation is relatively low, for example 20% or less, then it can be intuitively seen that most of the transmitted power is effectively an unmodulated signal. In fact, we can also tell intuitively that the average transmitted power will lie somewhere between the values for the “1” and the “0”.

The phase insensitivity of an amplitude modulation detector can be exploited so as to allow a phase modulation to be imposed on the transmitted signal such that values corresponding to a “1” and a “0” occur on both sides of the quadrature axis 36. It can then intuitively be seen that the average of the modulation signal can be reduced below that of the “0” and in fact can be brought close to a position at the origin of the phasor diagram.

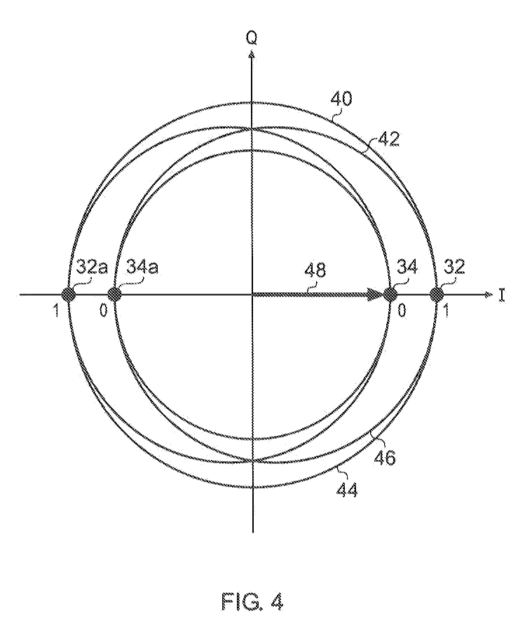

Such a modified transmission scheme is shown in FIG. 4. Here two values corresponding to a “1” exist, namely the value designated 32 as shown in FIG. 3 and a corresponding, value 32a having the same magnitude but the opposite phase such that it occurs on the negative side of the in-phase axis in the phasor diagram. Similarly the value corresponding to the zero 34 has a complimentary value 34a having the same magnitude but a 180° phase shift such that it occurs on the negative side of the in-phase axis in the phasor diagram. It can therefore be seen that, in amplitude terms, the greater amplitude always corresponds to a “1” and the lesser amplitude always corresponds to a “0” so that a receiver that only demodulates the amplitude component of the signal and which ignores the phase will not be affected by whether the transmitted constellation point is on the positive or negative side of the origin. Thus, for such a receiver, constellation point 32a is identical to constellation point 32.

As part of the modulation scheme a determination has to be made as to whether to use the in-phase constellation points, 32 and 34, or the anti-phase constellation points 32a and 34a to transmit the data. This choice can advantageously be made from a random data source, such as a random number generator, which is uncorrelated with the data which is being transmitted. Thus a “1” bit from the random number generator might correspond to use of the in-phase set and a “0” from the random number generator might correspond to use of the anti-phase set. However the opposite mapping could equally be used. It is, however, important to ensure that both pairs of constellation points are used substantially equally in order to obtain a zero DC condition and also to ensure that there are no strong patterns or correlations which might themselves produce unwanted spectral components. These conditions are generally satisfied by the use of a pseudo-random binary sequence which, in trials, has been found to work satisfactorily.

In practice, instantaneous changes of the amplitude and phase cannot be achieved. Therefore the signal cannot instantaneously hop between the points 32, 34, 34a and 32a. It therefore has to follow a trajectory from one point to the next. Furthermore, it is not desirable for the signal amplitude to merely traverse along the in-phase axis between, for example, point 32a and point 34 as in so doing the signal would pass through both, point 34a which might lead to transmission of corrupt data and also through the origin thereby creating a signal with a very large (100%) modulation index. Large modulation indexes are not desirable as they interfere with the transfer of power from the reader/writer to the passive device.

The solution chosen in GB 2437350 is a trajectory (which is implemented as a phase modulation) which substantially maintains the amplitude between that of the zero bit and one bit levels but which rotates the phase of the modulation signal around the constellation (phasor) diagram through substantially 180° to change between the in-phase and anti-phase sets of constellation points. Such a trajectory is schematically shown in FIG. 4. Starting at point 32, it can be seen that anti-clockwise rotation around the phasor diagram can be used to follow trajectories 40 or 42 to constellation points 32a or 34a, respectively.

However from point 32 it can also be seen that rotation in the, clockwise direction can be used such that trajectories 44 and 46 may be followed to the anti-phase constellation points 32a and 34a respectively. Similar trajectory paths exist from the constellation point 34 to the constellation points 32a and 34a, but have not been numbered so as to improve the clarity of the Figure. It can therefore be seen that, during the transition period from, for example. constellation point 32 to constellation point 32a, the magnitude of the transmitted signal remains substantially invariant or varies monotonically and hence ripple is not introduced into the power supply of the passive device. It is, of course, necessary to modify the reader/writer unit in order to be able to transmit a signal in accordance with the constellation diagrams shown in FIG. 4 and hence it is necessary to be able to modulate the phase of the signal to introduce phase changes into the transmitted signal. This could be achieved using a quadrature modulator fed by appropriate in-phase and quadrature phase signals. Indeed, the scheme is in principle extendable to large numbers of constellation points. as long as one set lie on a circle have a radius representing a “0” and the other set lie on a circle having a radius representing a “1”. I-Q modulators are especially suited for encoding schemes having lots of constellation points. However, the transmission scheme can also be introduced by a relatively simple modification of the AM modulators already embedded in the reader/writer units for use with the passive devices. This modification is particularly suited to schemes having low numbers of constellation points. Such reader/writer units already include an amplitude modulator and a frequency synthesiser in order to generate the RF carrier. So all that is needed is to add phase modulation. However, since frequency and phase are closely related and in fact frequency is the rate of change of phase, then the phase component of the modulation signal can be differentiated and this differentiated signal applied to a voltage controlled oscillator input as a frequency modulation to achieve the same result.

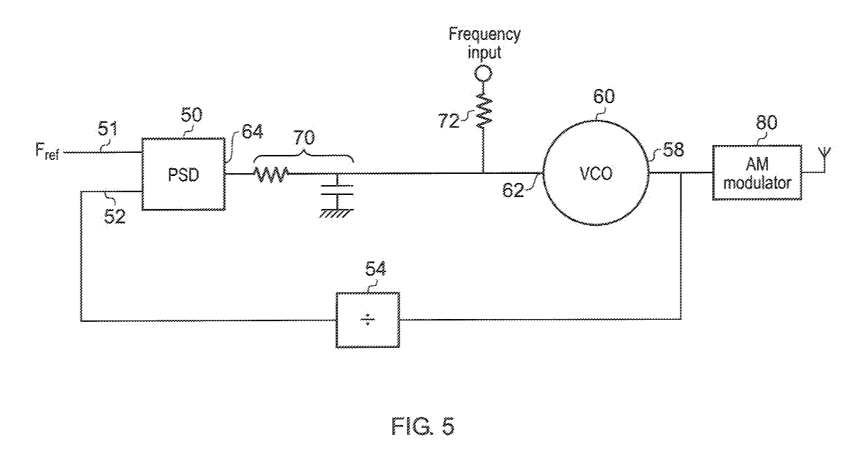

FIG. 5 schematically shows a modulator within a reader/writer unit which has been modified in order to enable a phase variation to be superimposed upon the amplitude modulated signal. The phase lock loop comprises a phase sensitive detector 50 which has a first input 51 which receives a frequency reference signal from a stable frequency source, such as a crystal controlled oscillator. The phase sensitive detector 50 also has a second input 52 which receives an output from a frequency divider 54 which in turn has its input connected to the output 58 of a voltage controlled oscillator 60. The voltage controlled oscillator has an input 62 which is connected to the output 64 of the phase sensitive detector 50 via a filter network generally designated 70. In use, the frequency output of the voltage controlled oscillator is divided down by the frequency divider 54 by a divide ratio N and supplied to the phase sensitive detector 50. The action of the phase sensitive detector is to try and match the frequencies and phases of the signals occurring at its inputs 51 and 52 and it produces a voltage output which is indicative of the error between the phases of the signals at its inputs. This error is low pass filtered in order to derive a control voltage for the voltage controlled oscillator therefore, providing the phase lock loop is appropriately designed, it will act so as to set the output frequency of the voltage controlled oscillator to be N times the frequency of the reference frequency. Given that the reference frequency is highly frequency stable, then the output frequency of the voltage controlled oscillator 60 can also be made to be relatively stable in frequency and well defined in frequency. The output of the oscillator is then provided to an amplitude modulator 80.

In order to allow the phase shift to be added to the signal, a further connection is made to the input of the voltage controlled oscillator, via a resistor 72 such that a further control voltage can be superimposed onto the oscillator input. Providing an appropriate conversion gain is applied then this further control signal can be used to make small perturbations to the voltage controlled oscillator's frequency output so as to introduce appropriate phase modulation to the oscillator output signal.

Given that the amplitude and phase components of the modulation signal are treated independently, and are effectively uncorrelated, it is worth considering in little more detail how they are generated. The amplitude component is generally straight forward, a digital data signal that is to be transmitted is simply filtered and DC shifted such that its mean signal level is the mean level between the two amplitudes in the constellation diagram.

As regards the phase component, we may assume that the modulation vector starts at an angle of zero degrees (that is lies along the positive axis of the in-phase component of the constellation diagram), and then one or more bits later swings with either a positive or a negative rotation through 180 ° . After a further one or more bits it swings back again preferably taking a reverse rotation to that which previously happened, such that it effectively retraces its path. Therefore, returning to FIG. 4, if a first phase rotation is anti-clockwise such that the modulation vector 48 follows the paths 40 or 42 into the anti-phase section of the phasor diagram, then the phase rotation will be a clockwise one so as to return the vector back to the in-phase section. Thus, the modulation vector does not travel through a complete 360° in any given direction of rotation.

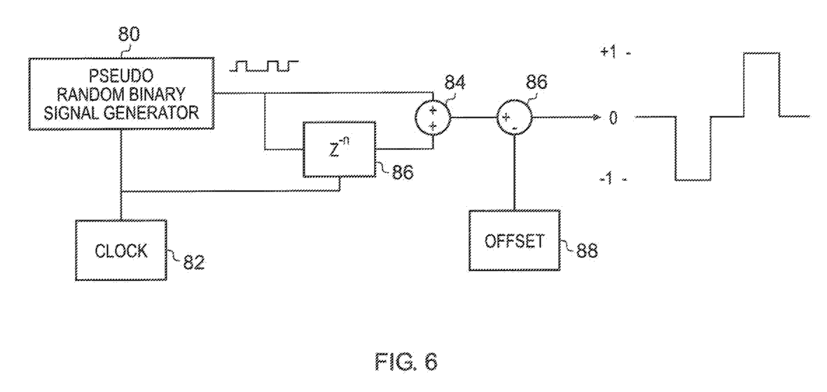

The behaviour of the modulation vector can be produced from a random bit stream by using duo binary encoding. A circuit suitable for generating such a phase change signal using duo binary encoding is schematically illustrated in FIG. 6.

A pseudo random binary signal generator 80, is used to generate a pseudo random binary sequence in response to timing signals from a clock 82. The pseudo random binary sequence is sent to a first adding input of an adder 84. The pseudo random binary sequence is also provided to a delay element 86 which introduces a delay of one or more clock pulses. The output of the delay element 86 is provided to a second adding input of the adder 84. Given that, in broad terms, the output of the binary random number generator 80 could either take a zero or a one then it can be seen that the output of the adder 84 can take the values zero, one or two. An output of the adder 84 is provided to an input of a second adder 86 which receives an offset signal for an offset generator 88, the offset corresponding in this example to a value of −1 such that the output of the adder 86 can take the values −1, zero or +1. These output values may, or may not, be low pass filtered and are then supplied to the input of the VCO via the resistor 72 . Apart form the optional low pass filtering, if the phase signal is to be used with the VCO in a frequency modulation implementation, then it should be differentiated to convert the phase modulation to an equivalent frequency modulation. The size of the resistor 72 is selected, based on a knowledge of the transfer characteristics of the voltage control led oscillator 60 so as to set an appropriate gain between the output of the adder 86 and the input of the voltage controlled oscillator 60 such that a desired phase of 180° is substantially achieved over the duration of one bit period of the duo-binary output signal at the output of the adder 86.

In the present invention the transitions from one constellation point to another are modified such that the transition is itself also going to give rise to a non-monotonic amplitude variation. Thus the transitions shown in FIG. 4 may be distorted slightly so as to follow a more bowed bath within the constellation diagram. This concept is easier to see when considering a more complex phasor diagram.

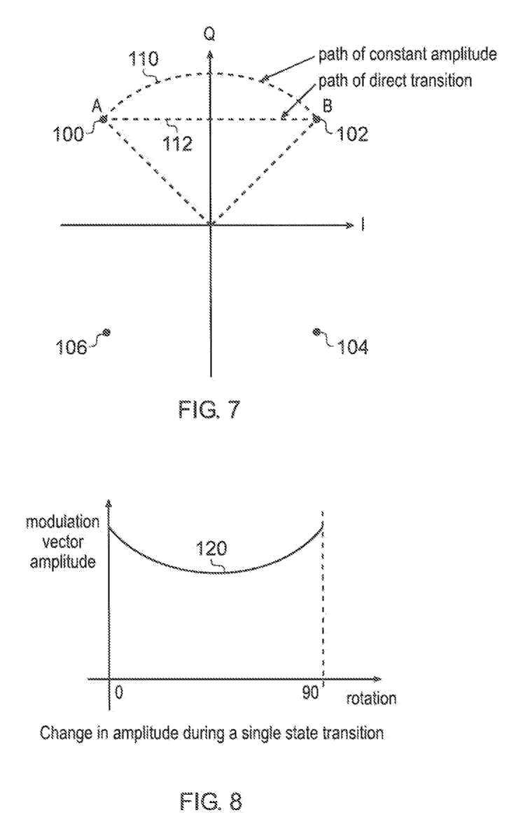

FIG. 7 shows a constellation diagram having four constellation points 100, 102, 104, and 106. If we consider a transition from point 100 to 102, in a regime where we are only seeking to change phase, i.e. we are not considering amplitude modulating the phase vector to encode data, then in the regime described hereinbefore the vector would progress doing path 110 representing a path of constant amplitude.

However, in the present invention the trajectory chosen deviates from the path of constant amplitude, for example, but not necessarily, along a path of direct translation 112. It can be seen that progression between the constellation points 100 and 102 along this path causes variations in the distance to the origin, and hence gives rise to an amplitude variation, as shown more clearly by the plot of amplitude versus rotation in FIG. 8. In FIG. 8 the plot of amplitude decreases with increasing distance from the constellation points, which occur at the 0° and 90° positions in this plot. Hence changes in amplitude are not monotonic.

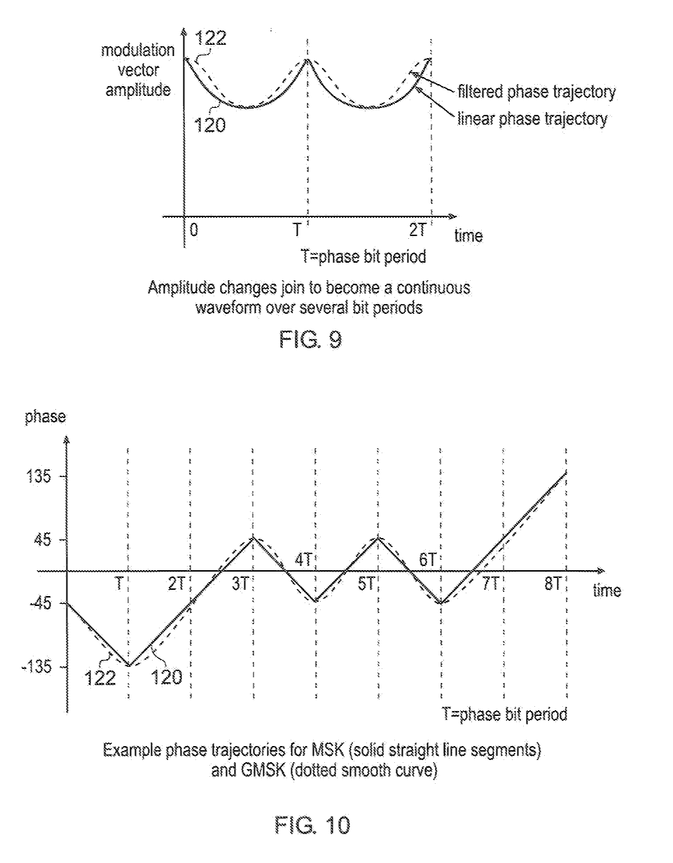

One consequence is that the rate of change of modulation vector amplitude is not continuous, which does not prevent this technique from being used. However performance is improved if the modulation vector phase trajectory is modified to be more sinusoidal, as indicated by chain line 122 in FIG. 9.

The production of the sinusoidal or substantially sinusoidal path 122 can be achieved by adding a further amplitude modulation to the carrier signal, but is most preferably done by varying the rate of rotation of the phase vector such that it rotates more quickly around the mid-point of its transition between adjacent constellation points and more slowly at the beginning and end of its transition between constellation points. The phase transition rate can be shaped with a Gaussian filter. The path 120 corresponds to a MSK modulation scheme whereas the filtering of the signal corresponds to a GMSK modulation scheme, both of which are known to the person skilled in the art.

FIG. 10 shows exemplary plots of phase versus time for a series of phase transitions having a transition period T. This confirms that the MSK scheme gives rise to abrupt changes in the rate of change of phase, whereas GMSK does not. As a result GMSK has a better constrained spectrum.

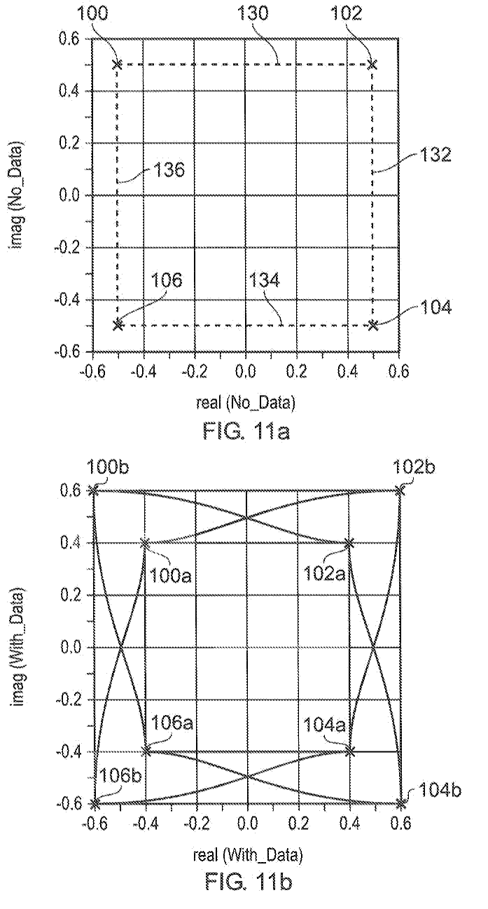

The desire to convey amplitude and modulated data complicates the transition paths within the constellation diagram. Initially consider an AM signal modulated to a modulation depth of 0.5 (compared to an arbitrary reference). Assuming that there are four constellation points 100, 102, 104 and 106 then we can represent the constellation points in the constellation diagram shown in FIG. 11a. The chain lines 130, 132, 134 and 136 represent transition paths within the constellation diagram.

Suppose now that we wish to convey data by way of amplitude modulation such that ‘0’s are represented by a modulation amplitude of 0.4 and ‘1’s are represented by a modulation amplitude of 0.6. In such a scheme each constellation point splits into a pair with, for example point 100a representing a ‘0’ and point 100b representing a ‘1’. The resultant constellation diagram is shown in FIG. 11b, with the possible transition paths being shown by solid lines.

The transmission scheme has a phase transition occurring in each T, and also can support transmitting a data bit in each period T. Each phase transition encodes a clock signal.

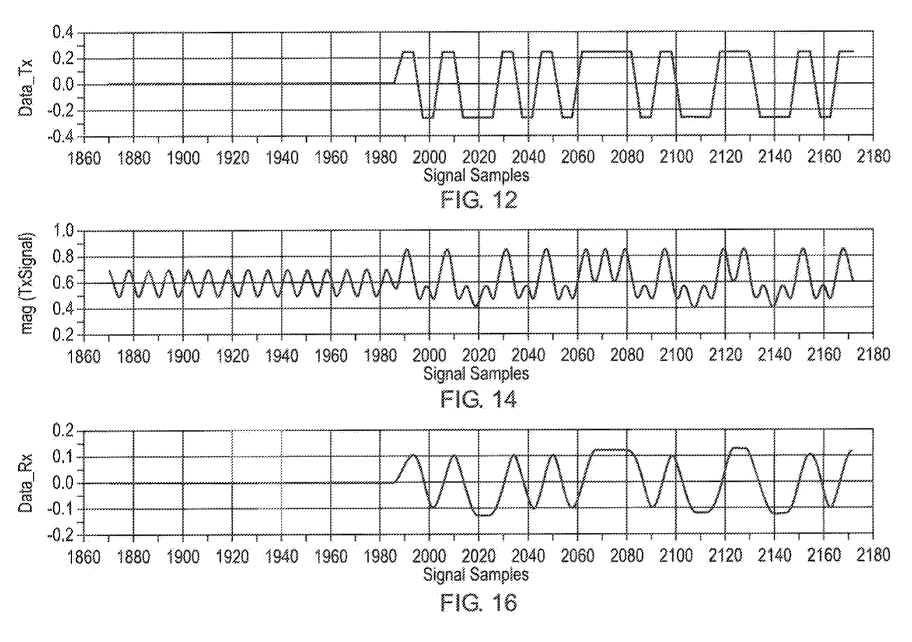

FIG. 12 represents a sampled filtered data sequence. In this example the data rate is eight times over sampled. During the period up to sample 1984 or so no data is being encoded. This might be because a memory spot reader/writer unit is receiving data from the memory spot. However a data sequence starts which encodes the bit sequence 101001010111 up to 2080. The sequence continues but need not be considered further. The effect of the filter is to smooth the transitions from a bit at one logic level to a bit at another. This is advantageous as it gives improved tolerance to delay element errors in a data recovery circuit of the receiver.

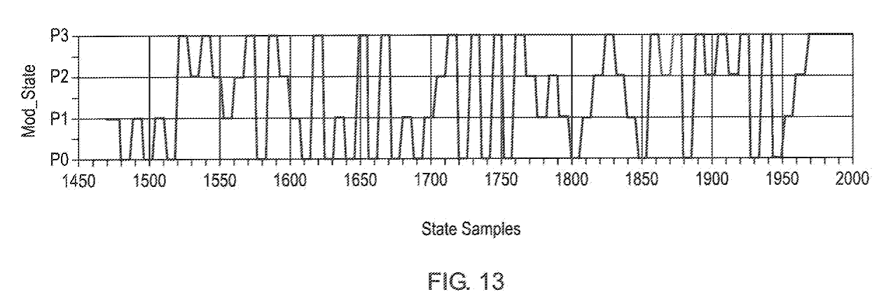

Meanwhile the phase of the carrier signal is also being varied by ±90° in synchronisation with the transmission slot for each data bit (irrespective of whether the data is being transmitted or not). This is shown in FIG. 13. Four modulation phase states labelled P0 to P3 are shown. Thus a rotation of −90° may make a phase transition from phase state P0 to P1. Similarly another −90° rotation from P3 takes us back to P0 and not P4 due to the modulo nature of the phase transitions. The phase changes give rise to spectrum spreading as described hereinbefore.

The transitions from one constellation point to an adjacent one in the absence of data, by ±90° phase rotations, are selected to take the paths shown in FIG. 11a. Thus even in the period preceding sample 1984 the phase transitions give rise to a modest amplitude change in the carrier wave as shown in FIG. 14. Once the data transmission is commenced then the amplitude is a combination of the data and amplitude variations due to phase transitions as set out by transitions within the constellation diagram in FIG. 11b.

FIG. 14 also represents, to a good approximation the signal obtained at an output of an envelope detector within, for example, a memory spot chip or an RFID chip.

In order for the memory spot device to derive the benefit from the transmission scheme it needs to recover both the data and the clock signal from the signal at the output of its envelope detector (AM demodulator).

In keeping with the cost sensitivity in the manufacture of such devices the apparatus for recovering the clock and the data from the combined signal needs to be simple—and inexpensive.

The inventor realised that as there is exactly one cycle of amplitude variation encoding the timing data per phase transition, then a moving averager with a window 1 bit long will produce a constant level output.

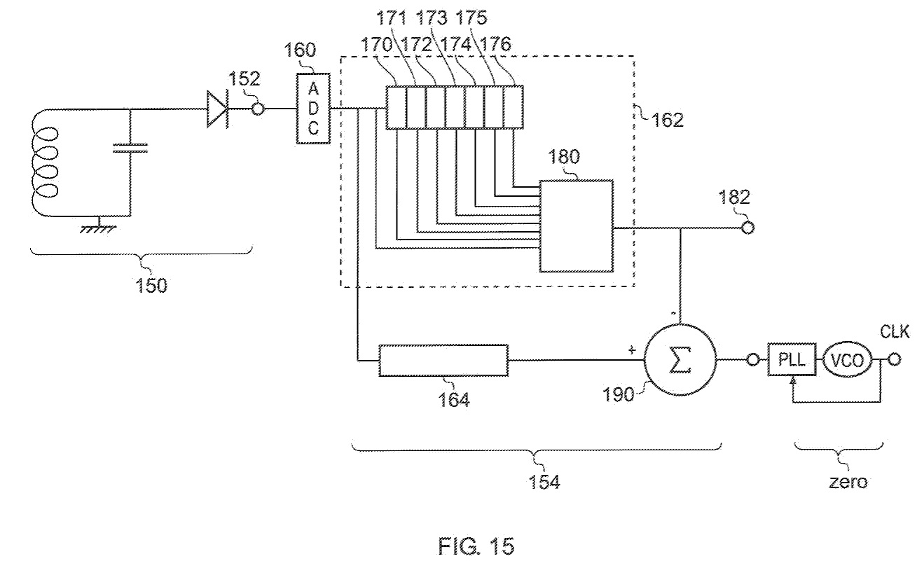

FIG. 15 shows an embodiment of the data and clock recovery circuit within a memory spot device. The memory spot device includes an AM demodulator 150 having an output provided to an input 152 of the data and clock recovery circuit 154.

The data and clock recovery circuit 154 can be implemented in the analogue or digital domains. The implementation described herein is in the digital domain. This is an appropriate decision as the memory spot will be fabricated to include digital memory and limited processing capability so the formation of a digital clock and data recovery circuit will not incur extra processing steps at manufacture. The demodulated signal is provided to an analog to digital converter 160 such that all subsequent processing can be done in the digital domain. The analog to digital converter may over sample the output of the demodulator such that several conversions are made per bit of data transmitted from a reader/writer to the memory spot device.

An output of the analog to digital converter 160 is provided to a moving averager 162 and a delay element 164. The moving averager comprises a plurality of delay elements 170 to 176 arranged in series. The outputs of several of the elements are combined at a summer 180 so as to form a finite impulse filter as is well known to the person skilled in the art. In fact to form a moving average all the delayed versions are weighted equally by 1/N where N is the number of delay taps and summed together.

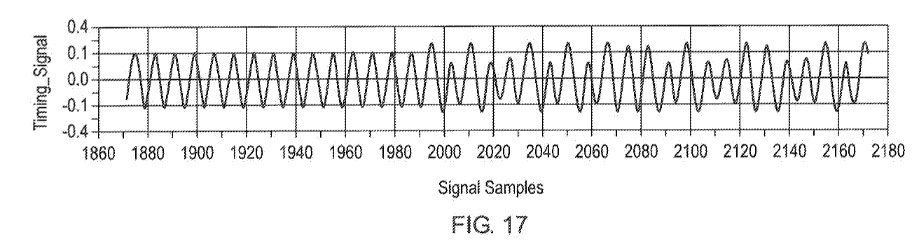

Thus the contribution to amplitude changes resulting from the clock signal are removed by the moving averager. The signal at an output 182 of the moving averager 162 is shown in FIG. 16. For clarity the waveforms in FIGS. 12, 14 and 16 are plotted against a common time axis as represented by the sample number. It can be seen that the output of the averager 162 is slightly delayed in time compared to the output of the demodulator. The purpose of the de lay element 164 is to introduce a matching delay in the path of the signal that has not passed through the moving averager. The recovered data signal is then subtracted from a time aligned version of the demodulator output at a subtractor 190 to recover the clock signal. A plot of the recovered clock signal is shown in FIG. 17.

The clock signal can then be used as a reference for a phase locked loop and associated voltage controlled oscillator, generally designated 200, so as to generate an internal clock CLK which may be used to control the timing of various functions within the memory spot, such as sampling times of the analog to digital converter 160 and read and write events to the memory of within the memory spot.

It should be noted that minor errors in the length of the filter time constant or timing errors in the moving averager can be tolerated as only a small bit of the tithing signal remains mixed into the data signal.

The receiver of FIG. 15 can be modified, for example by passing the averaged signal through a decision threshold to generate a squared data signal prior to providing it to the subtractor 190.

It is thus possible to encode timing information in a way that does not restrict the data throughput and which does not degrade the power spectral density of a reader/writer for use with passive devices such as RFID tags or memory spots.

1. A modulation scheme for modulating a signal transmitted from a first device to a second device which is energised by the signal, wherein the first device is further arranged to amplitude modulate the signal at a data rate, and wherein the method further comprises phase modulating the signal at a clock rate synchronised with the data rate, and wherein the phase modulation is arranged to cause a non-monotonic change in the signal amplitude.

2. A modulation scheme as claimed in claim 1, in which the phase modulation comprises a plurality of transitions between adjacent constellation points in a constellation diagram when the phase of the carrier signal is represented on the constellation diagram.

3. A modulation scheme as claimed in claim 2, in which the transitions occur along a trajectory such that a magnitude of the signal initially diminishes before increasing again.

4. A modulation scheme as claimed in any of the preceding claims, in which the phase transitions are a rotation by substantially 90 degrees.

5. A modulation scheme as claimed in claim 4, in which the rate of rotation varies during transition.

6. A reader/writer device for use with a passive device arranged to be irradiated with RF energy by the reader/writer device, wherein the reader/writer device modulates an RF carrier in accordance with the method of any of the preceding claims.

7. A receiver for recovering timing and data information from a signal, comprising an envelope detector for demodulating the signal to produce a demodulated signal;
a filter for filtering the demodulated signal to remove or attenuate amplitude variations due to the timing information so as to produce a data signal; and
a timing recovery circuit for forming a difference between time aligned versions of the demodulated signal and the data signal so as to recover the timing information.

8. A receiver as claimed in claim 7, in which the filter is a moving average filter.

9. A receiver as claimed in claim 7 or 8, in which the filter is a digital filter.

10. A receiver as claimed in any of claims 7 to 9, in which the timing recovery circuit includes a delay line to bring the output of the envelope detector into time alignment with the data signal.

11. A passive device arranged to be irradiated with an RF signal and to recover energy from the signal so as to derive power to operate the device, further including a receiver as claimed in any of claims 7 to 10.

12. A passive device as claimed in claim 11, wherein the passive, device is a memory spot.
